(19) United States
(12) Patent Application Publication
(10) Pub. No.: US 2014/0103962 A1
(43) Pub. Date: Apr. 17, 2014

(54) HIGH-SPEED GATE DRIVER FOR POWER SWITCHES WITH REDUCED VOLTAGE RINGING

(71) Applicant: SL3J SYSTEMS S.A.R.L., Gardanne (FR)

(72) Inventor: Sami AJRAM, Gardanne (FR)

(73) Assignee: SL3J SYSTEMS S.A.R.L., Gardanne (FR)

(21) Appl. No.: 13/649,372

(22) Filed: Oct. 11, 2012

(51) Int. Cl. H03K 3/00

(52) U.S. Cl. 327/108

(57) ABSTRACT

A fast power switch comprises one or more field-effect transistors, such as pull-up and pull-down transistors, that are coupled to a load. Respective driver electronic circuits for each of the field-effect transistors include parallel first and second drivers with a shared driver output coupled to a gate of the field-effect transistor. The first and second drivers are operative to switch the shared driver output for the appropriate field-effect transistor in response to a transition (e.g., low-to-high or high-to-low) at a driver input terminal. A control circuit enables the stronger second driver in response to a transition at the driver input terminal and subsequently disables the second driver once a transition threshold at the gate of the field-effect transistor(s) is crossed. The weaker first driver is sized to damp reactive energy at the load to minimize ringing.

### TECHNICAL FIELD

The present invention relates to electronic power switches with modifications to the gate drivers for (1) accelerating switching and (2) eliminating or reducing voltage oscillations or ringing.

### BACKGROUND ART

The input driver of a power switch, such as the gate driver of a power-MOSFET (T_{H} or T_{L} in FIG. 1), is usually designed to handle source and sink currents able to charge and discharge the gate capacitance in a very short duration. A series resistor R_{GL} is usually added between the driver and the gate which is assumed to attenuate or prevent gate oscillations mainly when the device turns-on [Laszlo Balogh, “Design and Application Guide for High Speed MOSFET Gate Drive Circuits”, Triode Seminar SEM1400 (2001)]. A Schottky diode is usually added in parallel with the gate resistor in order to increase the sourced current and insure a sharp turn-on transition. Some designers recommend adding a few nano-Henry series inductance L_{GL} between the driver and the gate of the power switch assuming this helps suppress any kind of gate oscillations (see FIG. 2). Another technique for accelerating the transition times consists of using Push-Pull Bipolar Junction Transistors which allow realizing very high source and sink drive capabilities (circuit illustrated in FIG. 3).

Such drive techniques are valuable as long as it is possible to achieve a compromise between the drive capability, or in other words the transition times, and the capability of damping the parasitic gate oscillations.

The drive techniques mentioned above could not be properly used in high switching frequency power management ICs for various reasons:
Damping resistors used in series with the gate circuit, although inherent to signal routing; require a bypass device such as a Schottky diode or a push-pull drive circuit based on CMOS devices.
Schottky diodes are not available in low cost CMOS or BiCMOS processes used for PMICs.
Push-pull CMOS based drivers do not provide sufficient drive at low supply voltage, and do not provide any drive below their threshold voltage which exposes the device to on-off toggling as it will be explained below.
Bipolar Junction Transistors do not provide fast enough transition times due to the storage of minority carriers in the base which increases the gate drive power loss and limits the switching frequency.

The integration of the Power Train (the High Side and the Low Side Power Switches T_{H}, T_{L} in FIG. 4) close to the gate driver in a single chip makes it possible to have a very strong gate drive capability (based on MOSFET switches scaled accordingly) and at the same time to minimize the intrinsic parasitic inductance of the power train. It makes it possible to achieve very short transition times and very high switching frequency.

The design of rapid gate drivers becomes critical in monolithic integrated power converters (FIG. 4), for which the switching frequency has constantly increased from few hundreds of kHz in the late 1990s to several MHz recently, in order to reduce the size of the passive components (storage inductor and filtering capacitors). Specific gate drive topologies and techniques can be employed for High Speed power converters depending on the power switch technologies such as reported in the U.S. Patent Application Publications US2007/0146020A1 of Richard K Williams and US2008/0018366A1 of John E Hanna. Such techniques allow solving functional problems encountered by circuit designers.

However, one of the important challenges in monolithic PMICs resides in the management of the excessive voltage ringing or energy ringing caused by the extrinsic parasitic self-inductance of the connections between the power train and the external capacitance C_{OUT}. The magnitude of the resonant energy depends on the magnitude of the self-inductance Lₗₒₒₚ of the current path also said current loop, as illustrated in FIG. 5 below. The example given in FIG. 5 represents the assembly drawings of a high frequency Buck Converter as utilized today in portable electronic devices where the PMIC (100) is assembled in a Chip Scale Package and the passive components are in surface mount device or SMD packages. The loop inductance value can be as high as 1 nH to 5 nH depending on the length of the current path (103 or 104) made of the input capacitor C_{IN} (107) the PCB trace and power switch (101 or 102).

The magnitude of the reactive energy ζ_{reactive} that is lost at the turn-off transition of the high side power switch can be estimated in a step-down or buck converter as follows:

$${ζ}_{reactive} = \frac{1}{2} {{L}_{loop} ( {I}_{out} + \frac{Δ {I}_{L}}{2} )}^{2}$$

where, Iₒᵤₜ is the DC output current and ΔI_{L} is inductor current ripple. It is thus assumed that the high side power switch (102), when turned on, let the current grow build in the inductor and reaches a peak value equal to

$$( {I}_{out} + \frac{Δ {I}_{L}}{2} )$$

before it is suddenly turned off. The current path (103) initially established from the input capacitor (107) through the PCB trace to the high side switch (102) is broken at the switching instant and the stored energy ζ_{reactive} in the parasitic path (103) self-inductance resonates and causes voltage ringing until the stored energy is entirely lost or a new cycle starts. A similar phenomenon occurs right after the low side switch turns-off.

The issue resides not only in the fact there is a resonant energy but mainly in the fact the electrical circuit constituted of the input capacitor (107), the PCB trace inductance (103), the power switches (101) and (102) has a very low series resistance and thus a high quality factor which causes high voltage and slowly damped ringing. It results in a higher voltage overstress for the power devices as well in a higher radiated and conducted noise causing additional electro-magnetic interference with surrounding electronic circuits.

PMIC designers always try to minimize the electrical stress on the components by reducing the size of the power switch drivers which introduces damping resistors in parallel with the power switching loop and helps damping the ringing. However, reducing the driver size results in a slower transition and limits the switching frequency of the converter.

FIG. 6 shows a detailed representation of the equivalent electrical circuit of a DC-to-DC converter power stage including the gate drivers and highlights the inherent damping elements that help absorb the resonant energy after each switching event. At the turn off of the high side switch (x02), the stored energy in the loop inductance (x03+x071) resonates with the parasitic capacitors of the power train (mainly x23, x20, x21 of x02) as well as with the on chip decoupling capacitor (x02). It is assumed that the on-state resistor (x12) of the low side switch (x01) and the series resistor of the decoupling capacitor (x52) are very low which means that the designer can add damping elements by optimizing the values of the drive sink and source resistors (x31 and x42 in this example) or by connecting external damping elements as proposed by previous techniques.

IC designers usually try to reduce the Electrical Over-Stress (EOS) in an empirical manner by researching a compromise between the power efficiency and the voltage Absolute Maximum Rating (AMR). They often reduce the size of the gate driver until AMR test passes.

The parasitic oscillations or ringing of power switches are more pronounced and more problematic when the device is switched at ultra-high frequency. S. Ajram reported in 1997 the existence of very aggressive parasitic oscillations (gate to source and drain to source waveforms) in a high frequency power converter operating at 100 MHz [Sami Ajram, “Ultrahigh Frequency DC-to-DC Converters Using GaAs Power Switches”, IEEE Trans. Power Elect. 2001]. Such ringing results in a reduction of the power efficiency, an increase of the voltage stress on the active components, an increase of conducted and radiated noise at high frequency.

This problem becomes recurrent in modern Power Management Integrated Circuits today due to the significant increase of the switching frequency. The high frequency crosstalk between the power train ringing after each switching event and the analog circuits, including the controller circuits themselves, requires a particular attention in order to isolate or completely blank the controller circuits during the ringing and manage to reduce the ringing amplitude and damp it as quickly as possible. The co-integration of various DCDCs on the same IC amplifies the problem which requires significant efforts for designers and increases the design cycle.

### SUMMARY DISCLOSURE

This invention consists of a new method that exploits the characteristics of the gate driver circuit to cancel or to damp the high frequency ringing effect that takes place at power switch terminals when driven between ON and OFF states with sharp transition times. This new method helps attenuate premature aging issues due to the voltage overstress induced by the ringing in power switching devices and reduces the amplitude of noise due to non-damped resonance inside the IC.

Although most techniques relative to gate drivers and power switch drivers seem to be in public domain today, the effect exploited in this patent does not seem to be previously known or employed in Integrated Circuit designs, and professionals employ empiric approaches to mitigate over-voltages stress due to energy ringing the parasitic reactive elements of a power switch.

This invention presents a new method for driving a high speed power switch that allows reducing or cancelling the voltage ringing at the power switch terminals, especially, but not limited to, those used in Integrated Circuits, such as power converters, audio amplifiers, high energy pulse generators. . . .

The voltage ringing between power switch terminals is responsible in high frequency power switching devices for Electrical-Over-Stress (EOS) that causes non recoverable damages in the device, premature aging or simply generate excessive parasitic noise that alters the operation of other sensitive circuits in the neighborhood. The voltage ringing across power device terminals is essentially due to the ringing of excessive energy stored in the parasitic inductors of power switch terminals when they switch from ON to OFF states or from OFF to ON states. This effect is more pronounced when the switching devices are involved in very high efficiency power conversion due to the very low power losses in each state (ON and OFF) and to the very low damping factor of the equivalent electrical circuit.

This invention describes a method for exploiting the parasitic elements of a power switch in conjunction with the design parameters of the drive circuit in order to allow substantial reduction and fast damping of the energy ringing involved after each switching. To do so, the driver is divided in multiple parts, a weak stage and a strong stage, that act in parallel at the start of each transition, ON-OFF, OFF-ON, or Tristate, in order to achieve a quick transition time, before turning off the strong stage and let the small stage maintain the new state, knowing that the equivalent series resistance of the weak stage of the driver is high enough to achieve efficient damping of the reactive circuit formed by the series parasitic inductors, the input capacitors and the output capacitors of the power switch, and the parasitic capacitor between the higher and the lower supply rails of the IC.

The sizing of the gate driver weak and strong parts takes into account the value of the reactive parasitic elements involved in the switching loops in order to achieve the required performance in terms of transition times and overvoltage limits tolerated for the power switches.

The technique proposed in this application can be extended for ultra-high speed drivers with capacitive load like switched capacitor systems or digital interfaces driving capacitive communication lines.

### BRIEF DESCRIPTION OF THE DRAWINGS

FIG. 1: (Prior Art) Electrical Schematic showing High Side and Low Side N-Channel power switches and their corresponding gate driver circuits that use series gate resistances and Schottky diodes in a step down DC to DC power converter (discrete or semi-integrated solution).

FIG. 2: (Prior Art) Electrical Schematic showing High Side and Low Side N-Channel power switches and their corresponding gate driver circuits that use series gate resistances and Schottky diodes in a step down DC to DC power converter (discrete or semi-integrated solution)

FIG. 3: (Prior Art) Electrical Schematic showing an N-Channel power switch and a push-pull gate driver in a step up DC to DC power converter.

FIG. 4: (Prior Art) Electrical Schematic showing complementary High Side and Low Side power switches and their corresponding gate driver circuits in a fully integrated step-down DC to DC power converter.

FIG. 5: PCB foot print and assembly outline of a high frequency DC to DC buck converter illustrating the component placement and visualizing the distances between the capacitors and the die terminals.

FIG. 6: Equivalent electrical circuit representing the parasitic elements of a power stage of a DC to DC converter when the high side switch (x02) is turned-off and the low side switch is turned-on (example given for a buck converter).

FIG. 7: Electrical schematic illustrating an improved gate driver solution (example given for a DC-to-DC buck converter).

FIG. 8: Electrical schematic illustrating an embodiment of the accelerated gate driver of a P-Channel MOS transistor using a CMOS technology (embodiment given the gate driver of the high side P-Channel switch T_{H}).

FIG. 9: Signal waveforms illustrating the operation of the fast gate driver shown on FIG. 7.

FIG. 10: Electrical schematic illustrating an embodiment of the accelerated gate driver in CMOS technology (embodiment given the gate driver of the high side switch T_{H}).

FIG. 11: Electrical Schematic showing the power switches and their gate drivers in a fully integrated DC to DC step down power converter.

FIG. 12: Equivalent electrical circuit representing the parasitic elements of a power stage of a DC to DC converter when the high side switch (x02) is turned-off and the low side switch is turned-on (example given for a buck converter).

FIG. 13: Simplified equivalent electrical circuit representing the high frequency resonating or ringing section in the power train in FIG. 12. It is assumed that the on state resistance of the power switch is very small compared to the impedance of the weak driver section (the strong section is tri-stated). It is also assumed that the on chip decoupling capacitor (x50) is omitted.

FIGS. 14 and 15: Waveforms of the accelerated gate driver incorporating a BLANK signal and a dual gate drive sections as proposed in the presented invention.

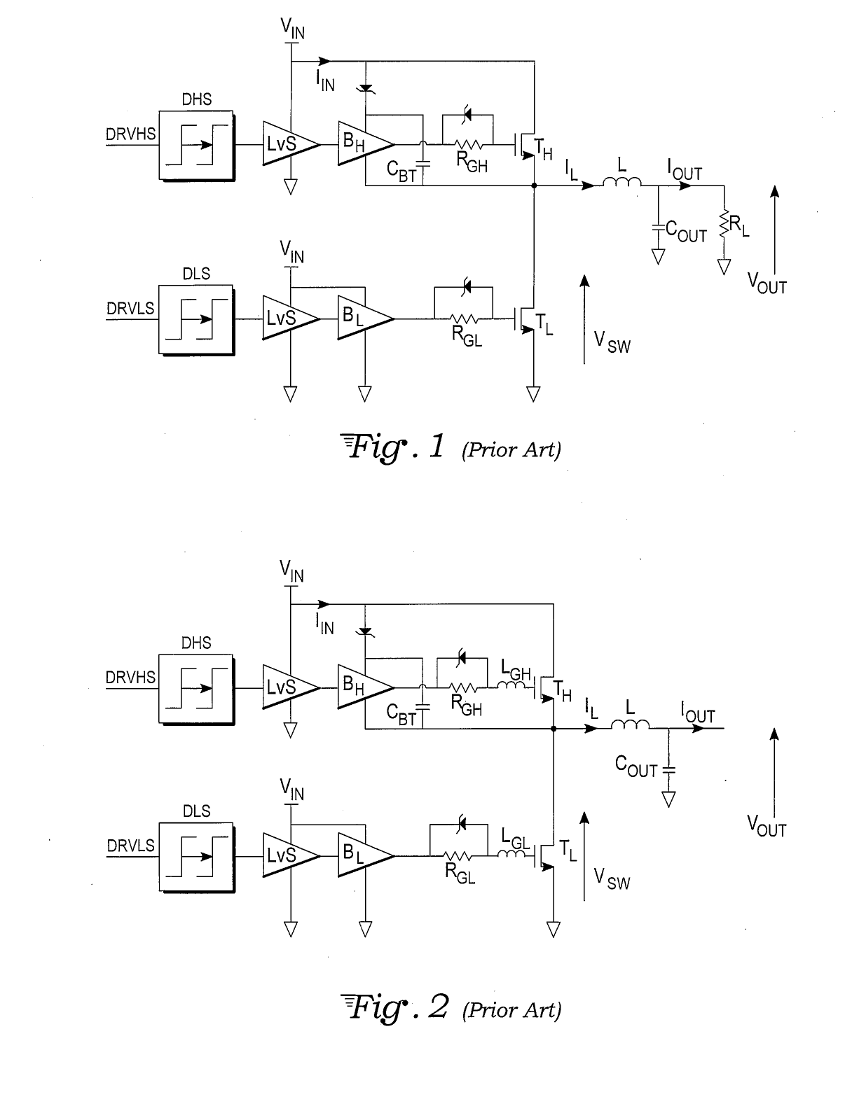

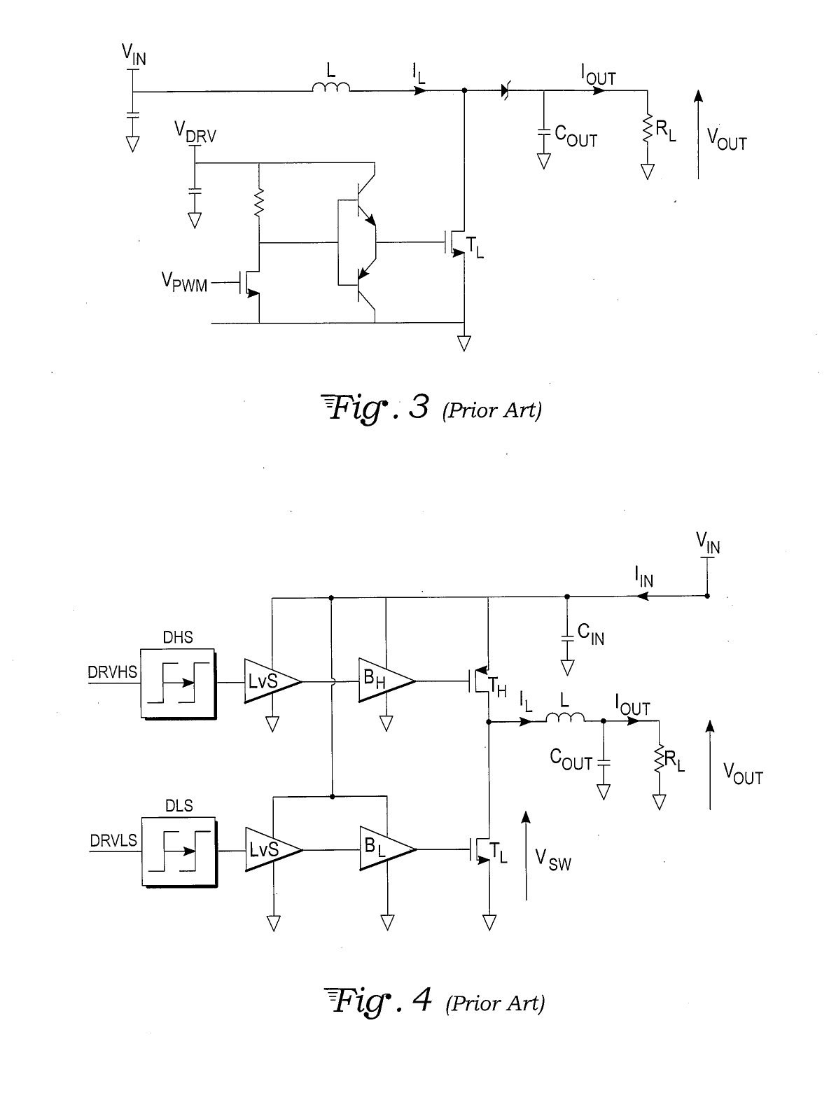

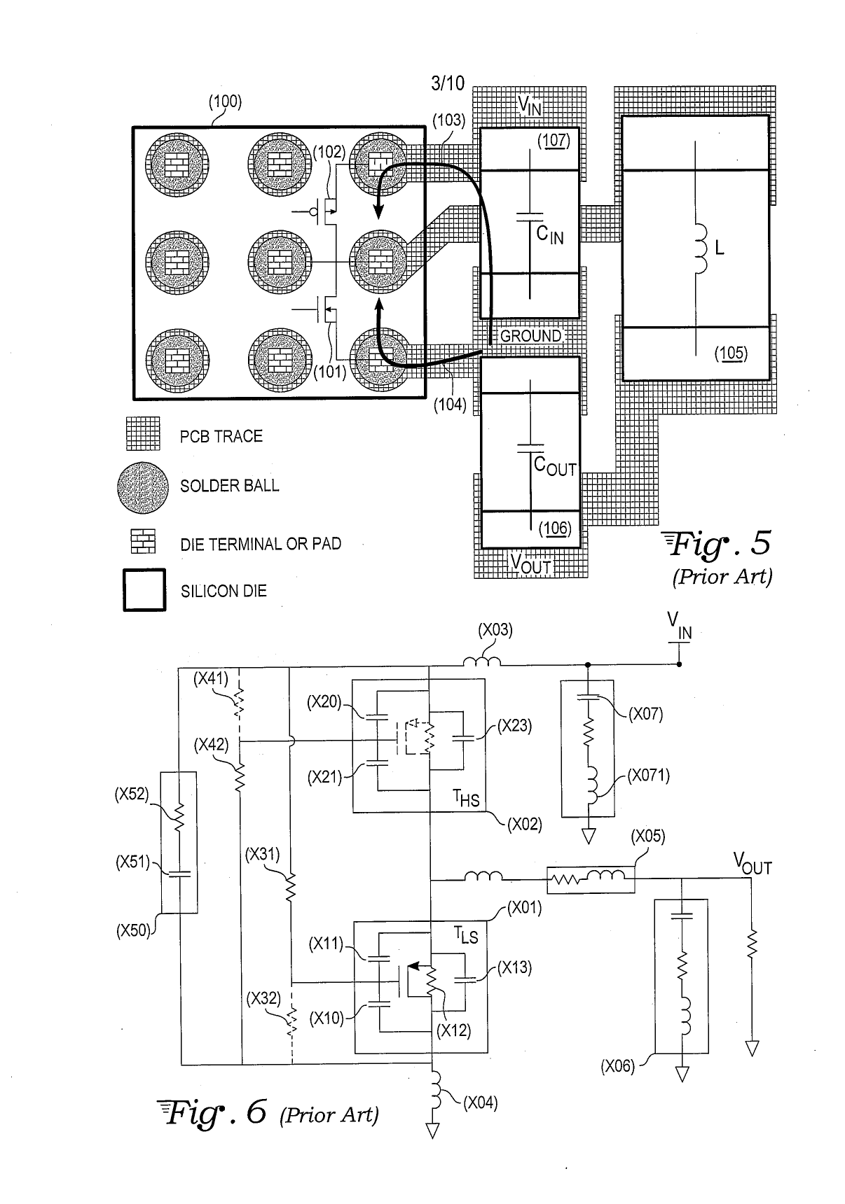

### DETAILED DESCRIPTION

The high speed gate driver in accord with the present invention employs a method for reducing voltage ringing in high-speed power switches that are subject to very high di/dt. In particular, this invention proposes a modification of the gate driver circuit in order to allow, firstly, ultra-fast charge and discharge times of the gate charge and secondly to efficiently damp the parasitic stored energy.

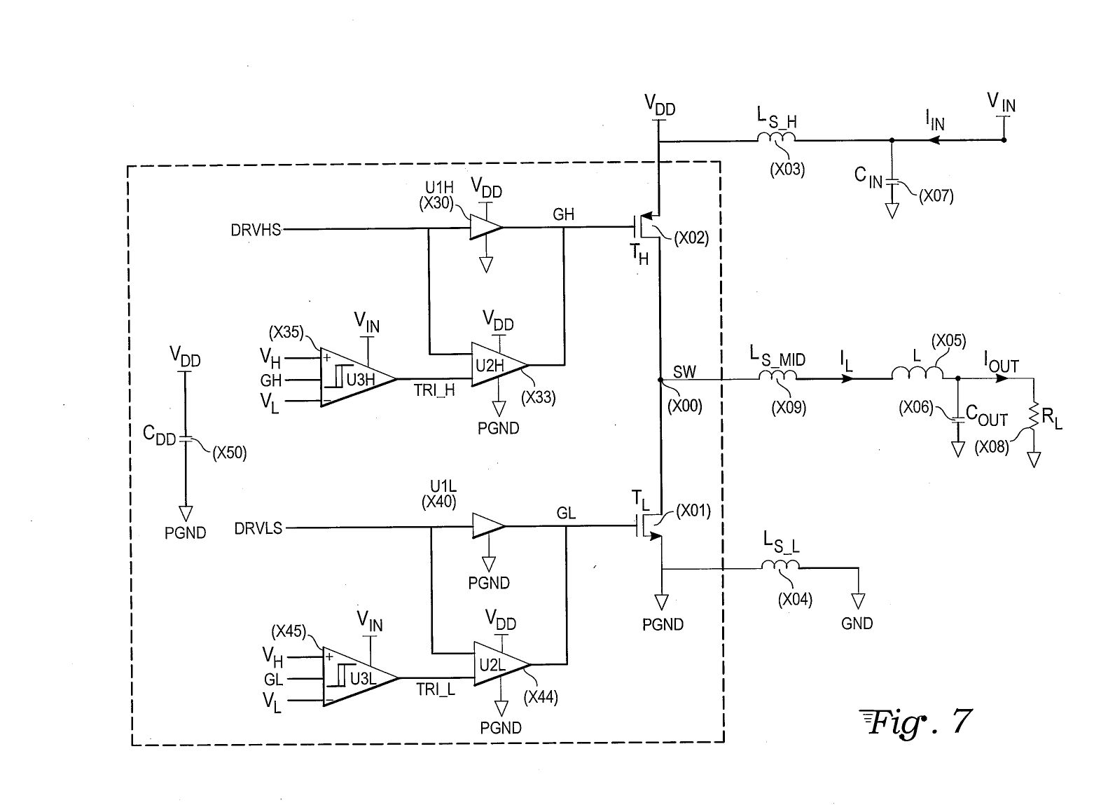

The new gate driver circuit works as follows (see FIG. 7):
Two parallel gate drive circuits, a weak drive section and a strong drive section are simultaneously activated in order to discharge the gate capacitance of the power switch in order to turn it off. It quickly reduces the conduction drain to source current to zero.
A fast voltage sensor is used to detect when the gate control voltage effectively drops to zero.
As soon as the gate control voltage drops to zero, the strong drive section is disabled. The weak driver section, still active, will maintain the new status of the gate.
The remaining energy in the interconnect parasitic inductor Lₗₒₒₚ will effectively cause ringing in the reactive circuit formed by Lₗₒₒₚ and the parasitic gate to source and gate to drain capacitors through the gate driver output impedance R_{DRV}_{_{—}}_{WK}. This last (R_{DRV}_{_{—}}_{WK}) must be designed to let the oscillation be damped as quickly as possible (1 or 2 pseudo-oscillation periods for instance).

The turn-on transition can be done in an equivalent and dual manner to insure the turn-on transition.

An exemplary embodiment of the invention is presented on the bloc diagram in FIG. 7 for a step-down or Buck DC to DC converter where, the High Side Switch Gate voltage GH is driven simultaneously by two driver sections, a weak section U1H (x30 and a strong section U2H (x33) that are activated in parallel in a first attempt in order to assure a fast transition. A comparator U3H (x35) with hysteresis is used to detect when the fast transition is achieved and disable the strong section of the driver until the next transition. The comparator compares the gate voltage with threshold voltages (V_{H} or V_{L}) that have to be appropriately selected to insure the completion of the turn-on or the-turn off transition before disabling the driver strong section. Similarly, the Low Side Switch Gate voltage GL is driven simultaneously by two driver sections, a weak section U1L (x40) and a strong section U2L (x44) that are activated in parallel in a first attempt in order to assure a fast transition. A comparator U3L (x45) with hysteresis is used to detect when the fast transition is achieved and disable the strong section of the driver until the next transition.

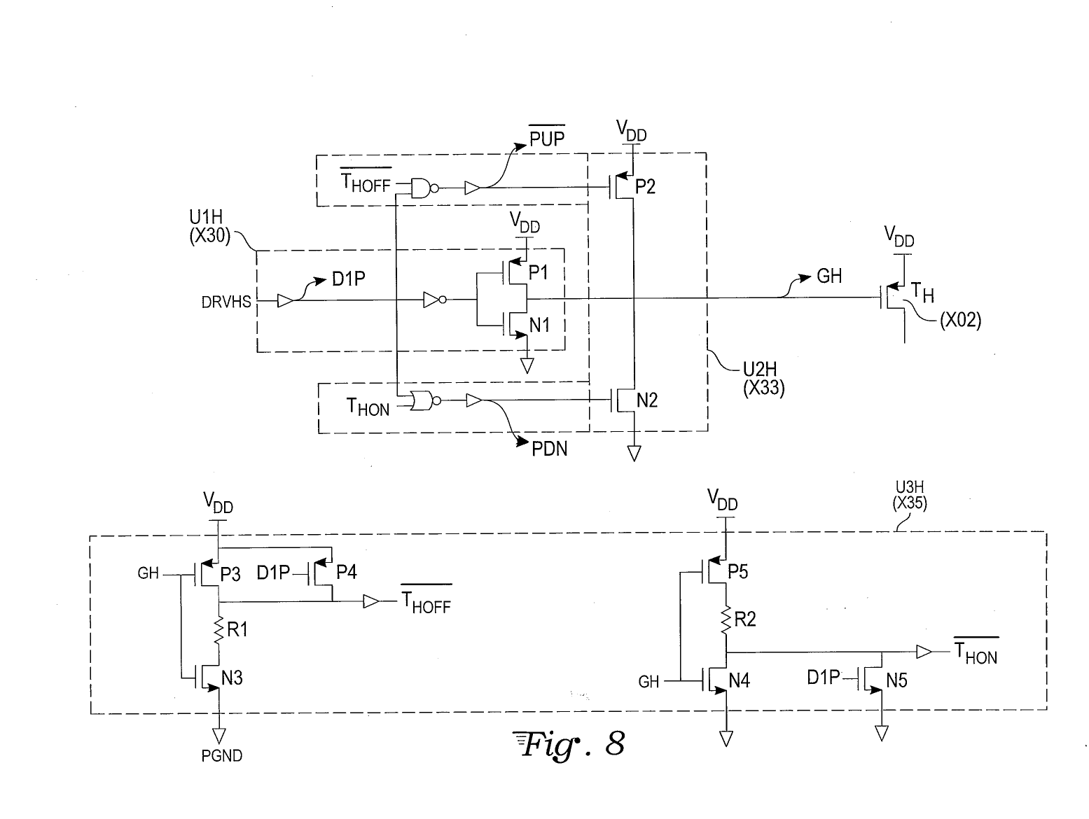

An electrical circuit embodiment of the present invention is illustrated in FIG. 8 for the high side switch drive circuit that is implemented in CMOS technology as follows:

The weak section of the high side driver (x30) is made of a cascaded and incremental size CMOS inverters ended by an power inverter that shows a source impedance R_{WKP} and a sink impedance R_{WKN} which are respectively the on state resistances of the P-channel transistor P1 and the N-channel transistor N1. Similarly, the strong driver section is made of transistors P2 and N2 that show a source impedance R_{STGP} and a sink impedance R_{STGN}. The size of the strong section has to optimize for fast turn-on and turn-off transition times of the power switch (x02) while the size of the weak section has to be optimized to assure proper handling of the gate control voltage against the high frequency variations of the still ringing signals in the circuit.

The sensor (x35) is made of 2 sections able to detect when high side switch is fully turned off or fully turned on. The off-state of (x02) is asserted when the transistor (P3) turns off. A turn-off flag T_{HOFF} is generated in order to disable the pull-up transistor P2 of the strong section. In a similar manner, the on-state of (x02) is asserted when the transistor N4 turns off. A flag T_{HON} is thus generated in order to disable the pull-down transistor N2 of the strong section.

A skilled in the art can easily adapt this circuit and employ the same technique and realize a driver for an N-Channel power switch.

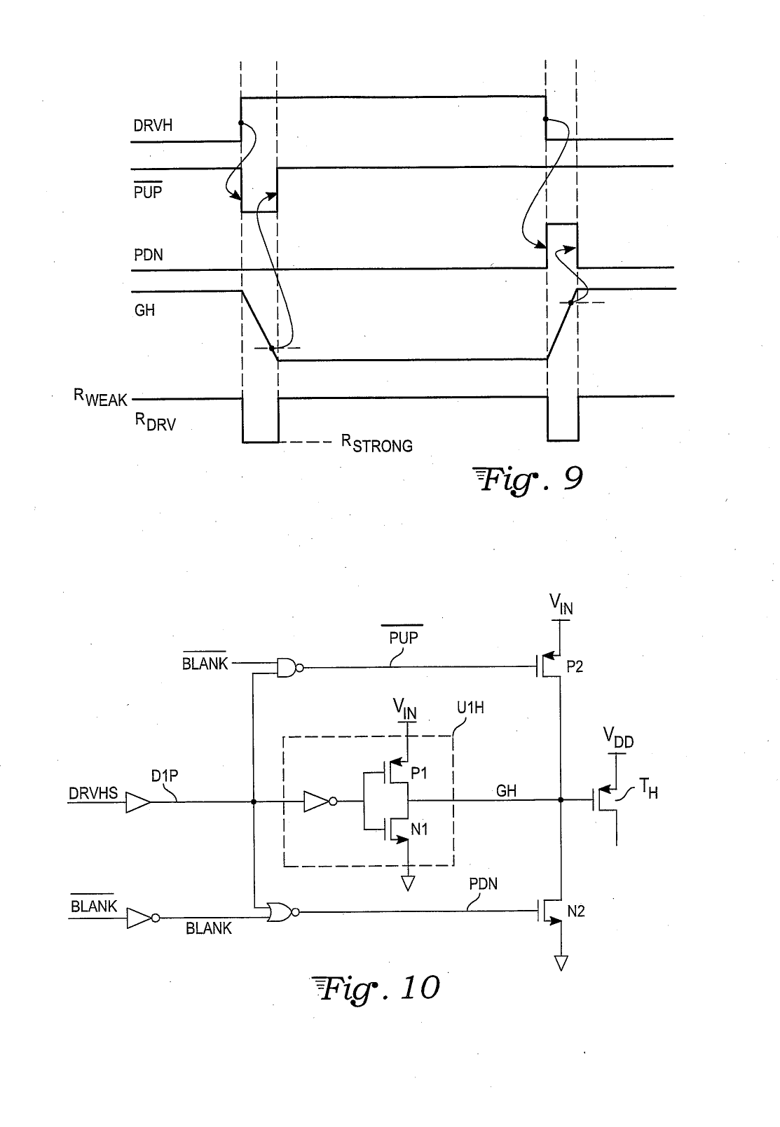

FIG. 9 shows exemplary signal waveforms associated to the implementation on FIG. 6. The transition starts immediately at the transition of the drive signal DRVH by simultaneously activating the weak and strong pull-up transistors P1 and P2 as illustrated in FIG. 7. The strong section is disabled when the gate signal GH reaches a turn-on threshold level (or a turn-off threshold level).

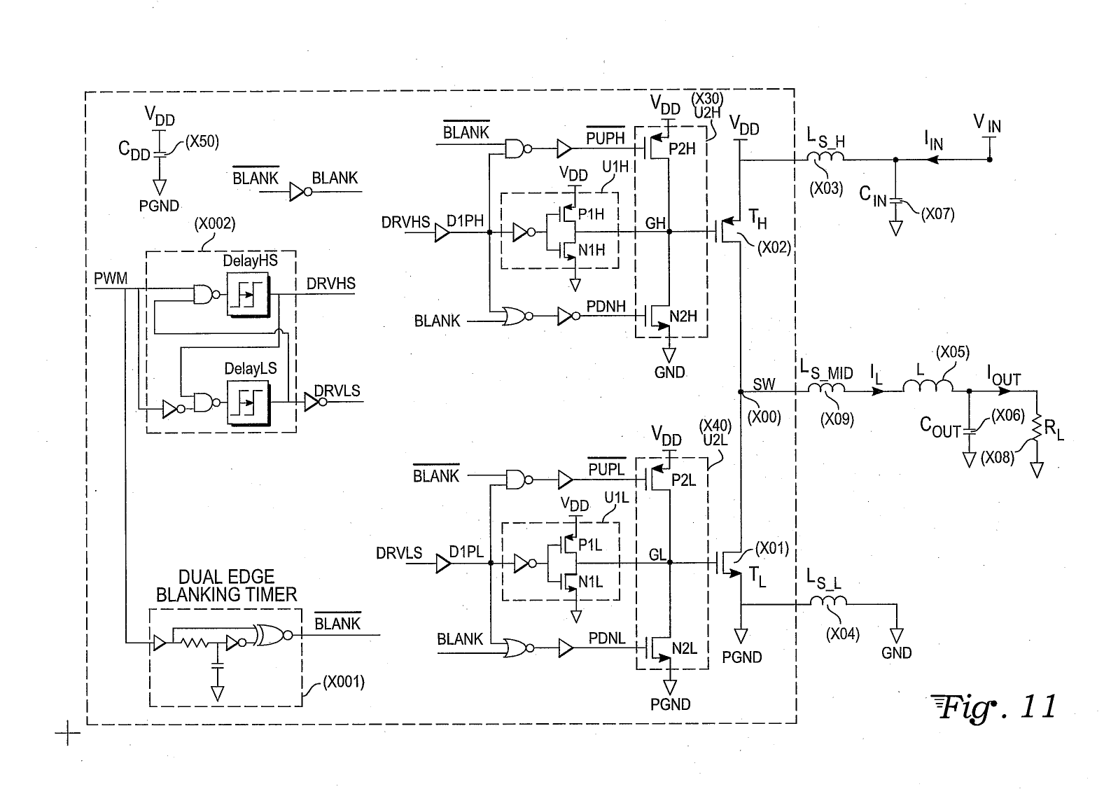

The exploitation of such technique can be made more sophisticated by combining the deactivation of the strong driver section with the effective transition of the power train output voltage in order to prevent any interaction and charge back-injection between the switch node SW (x00) through the miller components (x11) and (x21) due to the sharp slope or the sharp dv/dt of node SW. However, the ultra-high switching frequency imposes various limitations that prevent from adding extra transition-detectors because they add propagation delays and significantly increase the minimum duty cycle or reduce the maximum duty cycle. We propose a better and much faster implementation of the strong/weak driver technique with a gate driver as presented for the high side driver in FIG. 10 where the detector signal is replaced by a Blank signal that activates the strong driver section at each transition for a duration that is longer than the estimated power train transition time. This implementation provides at the same time a strong drive capability during the power switch transitions and the minimum propagation delay between the drive signals (DRVHS or DRVLS) and the power switch gates GH or GL.

The accelerated driver using the Blank signal is suitable for ultra-high frequency because it can be used with a Break-Before-Make drive technique (x002) as illustrated in FIG. 11 where the delays between the high side and the low side drive signals integrate feed-forward delays without any feedback or gating delays. The operation is illustrated on the waveforms in FIG. 14 based on the embodiment proposed in FIG. 11: The Blank signal is generated by a Dual Edge Blanking Timer (x001) in order to enable the strong driver sections (x30) and x(20) for a short duration after each PWM drive signal transition. This technique allows realizing very sharp transition times thanks to enabling a strong and low output resistance drive section. Once the gate signals transitions are achieved, the Blank signal returns to 1 which disables the strong drive section and enables the weak drive section for which the output resistance is high enough to quickly damp the resonant energy stored in the parasitic loop inductance.

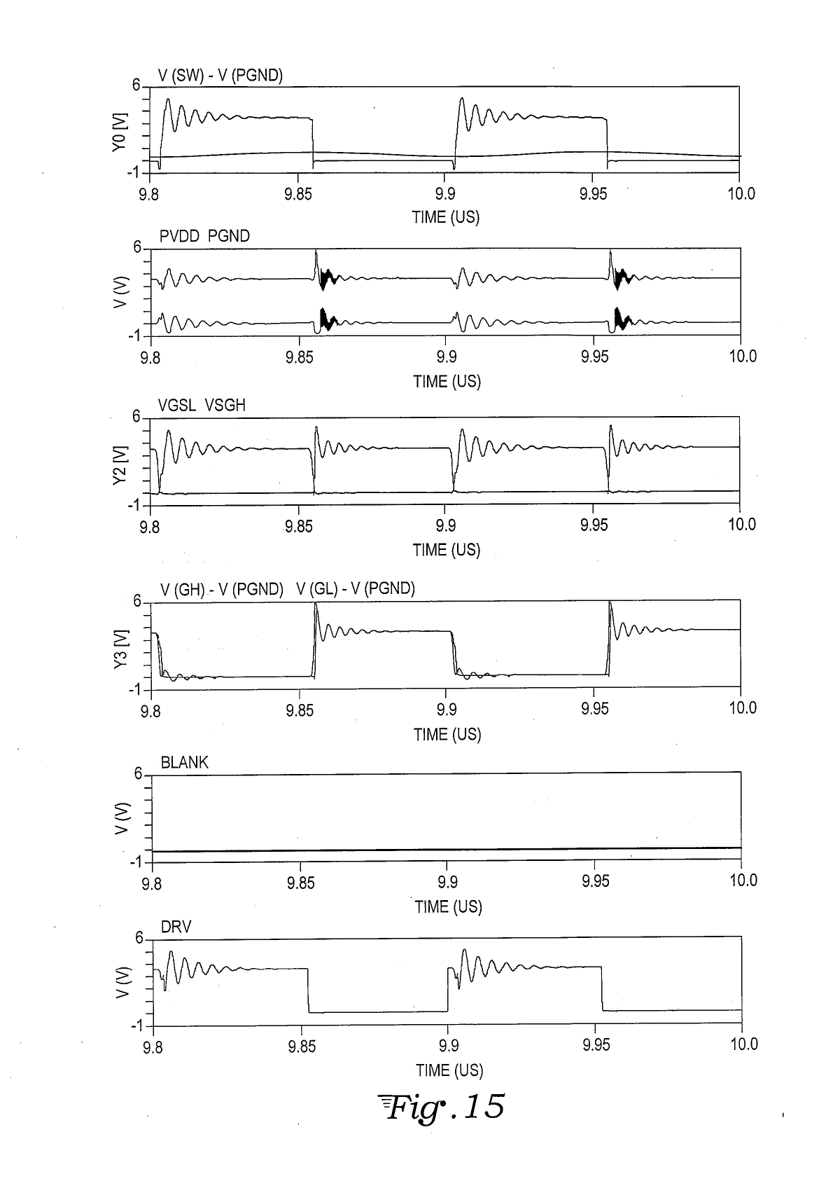

FIG. 15 is given for the sake of comparison where the blank signal is forced low which enables the strong driver section permanently. FIG. 15 clearly shows much longer duration of voltage ringing across the power switch control terminals.

### Sizing the Driver Sections

### 1. Sizing the Strong Section of the Gate Driver

It is possible to determine an optimum size for the strong section of the driver of the power switch with respect to the desired power switch turn-on time (or turn-off time) that allow achieving the highest power efficiency of the power switch stage. Such transition time are known to be proportional to the product of the driver output impedance by the power switch equivalent input capacitance. A rule of thumb can be used where the transition time is made equal or slightly smaller than one percent of the switching period. Other target values can be used by skilled in the art designers in order to achieve lower power losses depending on the power switch performance and circuit architecture.

### 2. Sizing the Weak Section of the Gate Driver

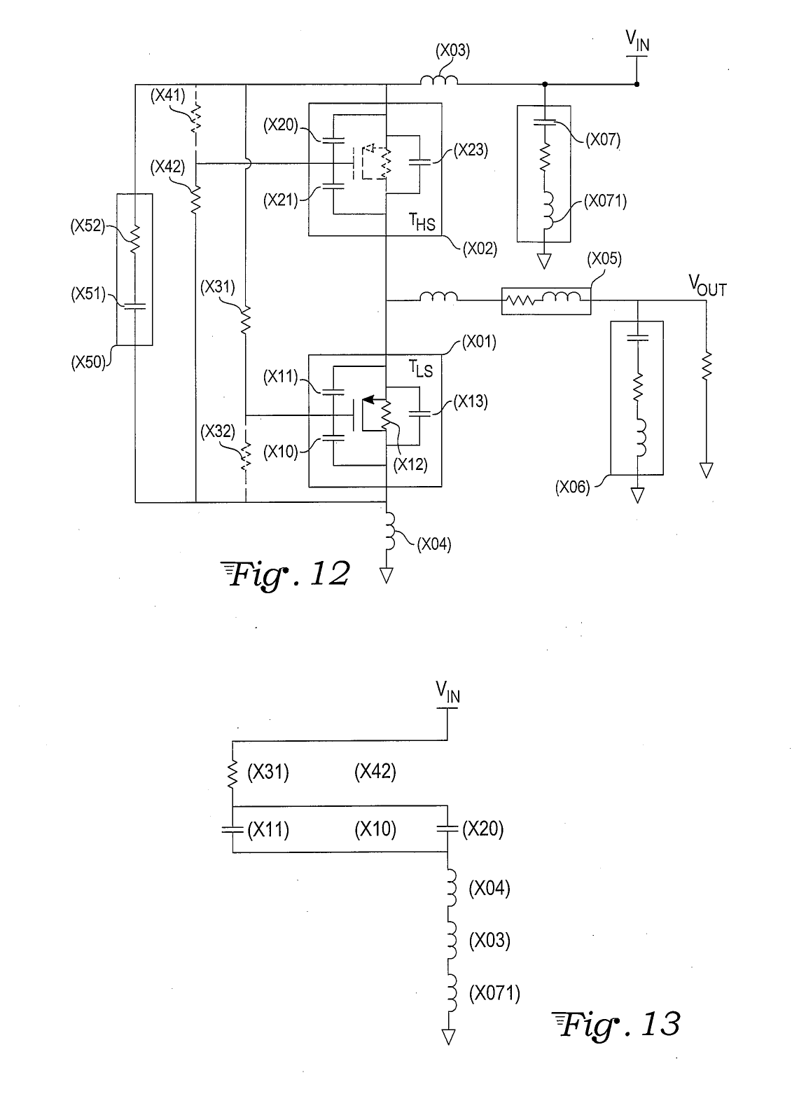

A skilled designer could evaluate the resonance factor of the parasitic circuit constituted of the series parasitic inductance of the power switch and the surrounding parasitic capacitors and resistors, and determine the size of the weak driver section in order to introduce a damping effect in the circuit at the end of the fast transition when the strong driver section is turned off. The example given here is illustrated on FIG. 12 (duplicate of FIG. 6) where it is assumed that at the end of the transition the low side power switch (x01) has been turned on and the high-side transistor has been turned off.

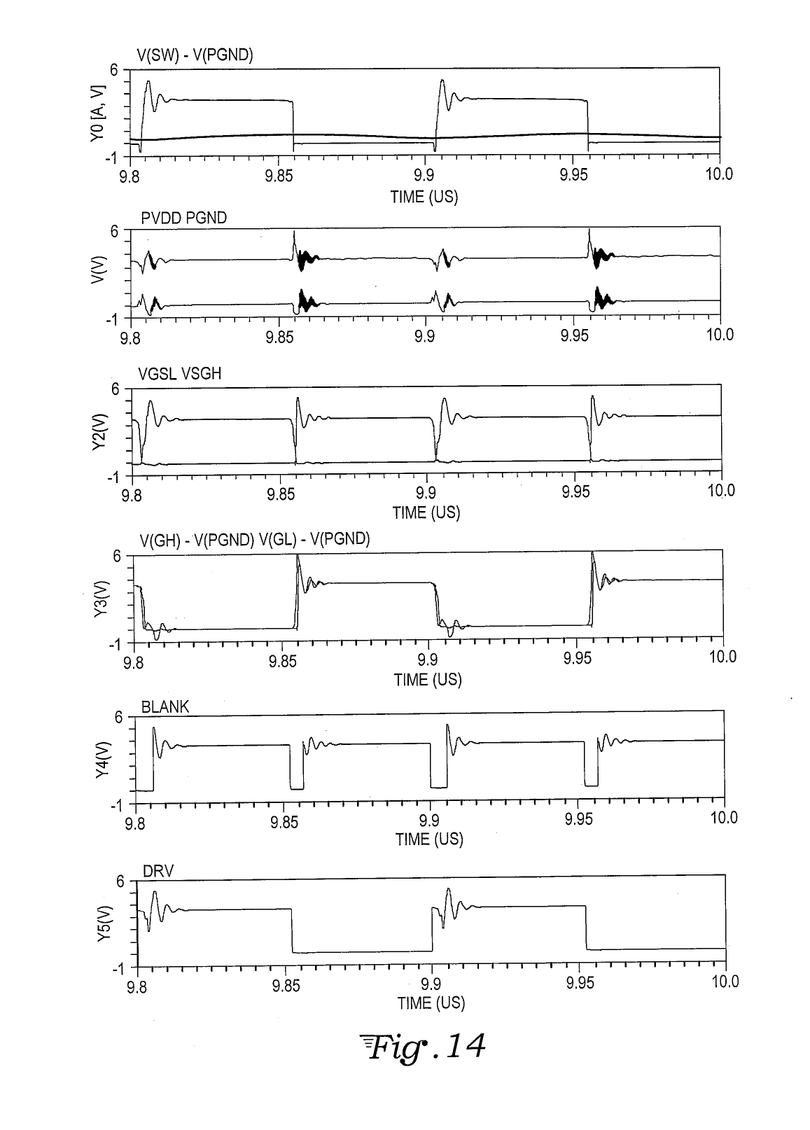

The low side power switch (x01) is assumed to have a very low on state resistance (x12) and a significant input capacitance (x10+x11). The simplified electrical circuit representing the resonating elements in the power switches is illustrated in the FIG. 13:
It is assumed that the on state resistance of the power switch is very small compared to the impedance of the weak driver section (the strong section is tri-stated).
It is also assumed that the on chip decoupling capacitor (x50) is omitted
The gate to drain capacitor of the high side switch (x21) is neglected
   In such situation, the damping factor ζ would be:

$$ζ = \frac{R}{2} \sqrt{\frac{C}{L}}$$

where
R is the sum of the driver impedances of the high side and the low side switches (x31) and (x41);
C is the sum of the input impedances of the high side and low side power switches (x20+x10+x11); and
L is the sum of the series parasitic inductance of the power switch loop (x03+x04+x71).

The damping factor ζ should be in a range from 0.7 to 3 and may be optimized to be equal to 1 or slightly higher in order to quickly damp or stop the energy ringing after the strong driver section is tri-stated and the weak driver section is maintained on.

The values could further be optimized by a person skilled in the art, by using EDA tools for instance, in order to account for additional extracted parasitics or use an appropriate equation to calculate the damping factor depending on the power switch and driver implementations.

1. A fast power switch, comprising:
a field-effect transistor coupled to a load;
a driver electronic circuit including parallel first and second drivers with a shared driver output coupled to a gate of the field-effect transistor, the first driver being sized such that a damping factor ζ is in a range from 0.7 to 3 to damp reactive energy at the load through gate capacitance of the field-effect transistor and the second driver being stronger than the first driver, the first and second drivers operative to switch the shared driver output in response to a transition at a driver input terminal, the driver electronic circuit further including a control circuit configured to enable the stronger second driver in response to said transition at the driver input terminal and to subsequently disable the second driver once a transition threshold at the gate of the field-effect transistor is crossed.

2. The switch as in claim 1, wherein the control circuit includes a timing circuit to disable the second driver after a time delay from the transition at the driver input terminal.

3. The switch as in claim 1, wherein the control circuit includes a voltage sensing circuit coupled to the shared driver output so as to detect a crossing of the transition threshold at the gate of the field-effect transistor.

4. The switch as in claim 3, wherein the voltage sensing circuit is characterized by hysteresis such that different transition thresholds are detected for low-to-high transitions of the shared driver output versus high-to-low transitions of the shared driver output.

5. The switch as in claim 1, wherein the second driver includes a three-state buffer with a first input coupled to the driver input terminal, a state control input, and a buffer output coupled to the shared driver output, the control circuit coupled to the state control input of the three-state buffer and operative to place the three-state buffer into a driven state in response to a transition at the driver input terminal and to place the three-state buffer into a high impedance state once the transition threshold is crossed.

6. (canceled)

7. A switch electronic circuit having a switch output coupled to a load, comprising:
a pull-up device having a control input and having an output connected to the switch output;
a pull-down device having a control input and having an output connected to the switch output;
a first driver electronic circuit with a first parallel-driver output connected to the control input of the pull-up device; and
a second driver electronic circuit with a second parallel-driver output connected to the control input of the pull-down device,
wherein each of the driver electronic circuits include:
(a) a first driver sized such that a damping factor ζ is in a range from 0.7 to 3 to damp reactive energy in the switch output through gate capacitance of the control input of the respective pull-up or pull-down device to which that first driver is connected;
(b) a second driver, stronger than the first driver, having an output connected to an output of the first driver as a parallel-driver output; and
(c) a control circuit configured to (1) switch the output of the first driver in response to transitions at a driver input terminal of the driver electronic circuit, (2) enable the second driver in response to the transitions at the driver input terminal of the driver electronic circuit, the output of the second driver driving in agreement with the output of the first driver while the second driver is enabled, and (3) disable the second driver after a delay triggered by the transitions at the driver input terminal.

8. The switch electronic circuit of claim 7 wherein the delay triggered by the transitions at the driver input terminal is provided by a timing circuit producing a timed delay in response to the transitions at the driver input terminal of the driver electronic circuit.

9. The driver electronic circuit of claim 8 wherein:
the timing circuit includes a dual edge-detecting timer circuit coupled to the driver input terminal; and
the timed delay is tuned by a resistor value and a capacitor value.

10. The driver electronic circuit of claim 7 wherein the delay triggered by the transitions at the driver input terminal is provided by a voltage sensing circuit coupled to the parallel-driver output and detecting the parallel-driver output completing at least a portion of an output transition.

11. The driver electronic circuit of claim 7 wherein the voltage sensing circuit includes at least one comparator with hysteresis.

12. The driver electronic circuit of claim 7 further comprising:
the first driver including a first buffer having a first input coupled to the driver input terminal, and a first output connected to the parallel-driver output;
the second driver including a three-state buffer that is stronger than the first buffer, having a second input coupled to the driver input terminal and a second output connected to the parallel-driver output, thereby connecting in parallel with the first buffer; and
the control circuit including a three-state control circuit coupled to the three-state buffer and directing the output of the three-state buffer to be in a driven state in a first response to a first event of the driver input terminal undergoing a low-to-high transition and in a second response to a second event of the driver input terminal undergoing a high-to-low transition, and directing the output of the three-state buffer to be in a high impedance state in a first delayed response to the first event and in a second delayed response to the second event;
wherein the first and second delayed responses are based upon the delay triggered by the transitions at the driver input terminal.

13. The driver electronic circuit of claim 7 wherein:
the first driver includes a P channel MOSFET as a first pull-up transistor and an N channel MOSFET as a first pull-down transistor; and
the second driver includes a P channel MOSFET as a second pull-up transistor and an N channel MOSFET as a second pull-down transistor.

14. (canceled)
